(19) United States
(12) Patent Application Publication
(10) Pub. No.: US 2007/0190796 A1
(43) Pub. Date: Aug. 16, 2007

(54) Method and apparatus for manufacturing a functional layer consisting of at least two components

(75) Inventors: Martin Dinant Bijker, Helmond (NL); Franciscus Comelius Dings, Veldhoven (NL); Marinus Franciscus J. Evers, Heeze (NL)

Correspondence Address: PILLSBURY WINTHROP SHAW PITTMAN, LLP, P.O. BOX 10500, MCLEAN, VA, 22102, US

(73) Assignee: OTB GROUP B.V., EINDHOVEN (NL)

(21) Appl. No.: 10/583,914

(22) PCT Filed: Dec. 16, 2004
(86) PCT No.: PCT/NL04/00876

§ 371 Date: Aug. 17, 2006

(30) Foreign Application Priority Data
Dec. 21, 2003 (NL) 1025094
Dec. 22, 2003 (NL) 1025096

(51) Int. Cl. H01L 21/302

(52) U.S. Cl. 438/727; 257/E21.17

(57) ABSTRACT

A method for manufacturing a functional layer includes introducing a substrate into a process chamber; generating a plasma by a DC plasma cascade source; depositing a first deposition material on the substrate under the influence of the plasma. At the same time, a second deposition material is applied to the substrate with a second deposition process. The functional layer has no catalytic function.

The invention relates to a method for manufacturing a layer on a substrate with the aid of a PECVD source.

In practice, there sometimes is the need to build up layers from various materials. Here, it can be an advantage when the materials are mixed with one another within the layer. The present invention contemplates providing a method and an apparatus with which such composite layers can be manufactured.

According to the invention, a method for manufacturing a functional layer is provided, where a substrate is introduced into a process chamber, where at least one plasma is generated by at least one plasma source, such as for instance a plasma cascade source, where at least one deposition material is deposited on the substrate under the influence of the plasma, while, at the same time, at least one second material is applied to the substrate with the aid of a second deposition process, while the functional layer has no catalytic function.

The plasma flowing from the plasma source preferably designed as a plasma cascade source usually has a relatively high outflow velocity, so that the plasma can accurately be aimed at the substrate in order to deposit the deposition material thereon. Further, the plasma makes precursors sufficiently chemically active to bind to eventually form the functional layer. For this purpose, the pressure in the process chamber can be maintained relatively low in relation to the pressure in each source. Further, ions formed in the plasma may be accelerated towards a surface to be covered by, for instance, the plasma and/or a suitable electric field for the purpose of deposition on that substrate. Due to the combination of the plasma source with a different deposition source, a mixed layer can be obtained in which different materials have been mixed with one another as a result of the two deposition processes taking place simultaneously.

Because the plasma is generated by at least one plasma source, preferably designed as a plasma cascade source, a high deposition rate of at least one deposition material can be obtained. In addition, use of this source makes an in-line method possible for manufacturing functional layers. As a result, the functional layers can be produced in relatively large numbers at a high rate.

An example of a possible use of the method according to the invention could, for instance, be the application of a ZnS:SiO₂ layer. Such layers are, for instance, used in the manufacture of rewritable DVDs. According to the prior art, the ZnS:SiO₂ layer is manufactured with the aid of a sputtering process. A disadvantage of this manufacturing method is that the masks used therein pollute very rapidly, which makes regular cleaning of the masks necessary with the corresponding loss of production capacity of the manufacturing process. In addition, the application of the layer with the aid of sputtering is fairly slow. With the aid of the method according to the invention, for instance the ZnS could be deposited from diethyl zinc (DEZ) and H₂S with the aid of the plasma source. The SiO₂ could, for instance, be deposited using a sputtering process. Alternatively, the SiO₂ can be deposited using a second plasma source, such as for instance a plasma cascade source, by supplying it with oxygen and silane or with a liquid Si precursor such as TEOS.

Another example of a possible use of the method according to the invention is the manufacture of anti-reflection, heat-resistant and/or optical filters for the automobile industry. For the purpose of the manufacture of car windows, by applying a film to the front and/or back side of a car window, a layered structure is effected. Here, use may, for instance, be made of a PET film. With the aid of the method according to the invention, to the PET film, layers can be applied with this functionality. One possibility is, for instance, a combination of layers consisting of MgF₂ and TiO₂. When applying coatings to large surfaces with great precision, the deposition rate is very important. With the aid of the method according to the invention, very high deposition rates can be realized. A combination process of sputtering for the metallic layers and a cascade arc process for the ceramic layers yields a huge advantage in the application rate. For instance, the TiO₂ could be formed by supplying titanium diethyl as a liquid precursor and O₂ as a reaction gas into the plasma of the plasma cascade source.

According to a further elaboration of the invention, the deposition material is supplied to the plasma outside the at least one plasma source in the process chamber.

In this manner, it can be avoided that the deposition material can pollute the source internally. For this purpose, for instance at least one volatile compound of this deposition material can be supplied to the plasma for the purpose of the deposition. In this case, the chemical composition of the functional layer can be controlled well by setting the supply of the volatile compound of the functional material. By setting the vapor pressure of the gaseous compounds of the elements to be applied, the chemical composition of the layer to be applied can be controlled. The volatile compound may also contain precursor material that can decompose in the material to be deposited.

According to a further elaboration of the method according to the invention, the second deposition process has been chosen from the group comprising PECVD, CVD, PVD, such as sputtering, hollow-cathode sputtering, vapor deposition optionally using boats, e-beam, and optionally supported by an ion process, ion plating, microwave deposition, ICP (inductive coupled plasma), parallel-plate PECVD, optionally honey comb electrode structures, and the like.

Each of these deposition processes has its own advantages for specific uses and materials. Depending on the desired layer, one or more of these processes can be deployed in addition to the PECVD carried out using the plasma cascade source.

According to an advantageous elaboration of the invention, at least one sputtering electrode comprising the deposition material is arranged in the process chamber, where the plasma is brought into contact with each sputtering electrode in order to sputter the substrate with the material of the electrode.

In this manner, the deposition material can simply be sputtered onto the substrate while preserving above-mentioned advantages. Preferably, the at least one sputtering electrode contains at least a part of both the at least one material and the other material to be deposited. By setting the weight ratio of the different materials in the electrode, the chemical composition of the functional layer can be controlled well. If necessary, a mixture of powders of the desired metals can even be taken as a starting material.

Further, the at least one sputtering electrode may contain, for instance, only carrier material of the functional layer. For instance, an electrode of aluminum oxide, silicon oxide, titanium oxide or zirconium oxide may be used. Of course, the corresponding metal of the intended carrier may also be used as an electrode. The deposition of that material may then be carried out in a gas atmosphere containing oxygen. Further, for instance gaseous compounds of the functional components to be deposited can be supplied into the plasma, for instance via supply channels provided in the electrode. After deposition, a thermal process at an elevated temperature, optionally under special gas conditions, for instance in a hydrogen flow, can then be carried out for the purpose of post-treatment of the functional layer.

The invention further relates to an apparatus for manufacturing a functional layer on a substrate, where the apparatus is provided with at least one plasma cascade source to generate at least one plasma, while the apparatus comprises means to introduce a first deposition material into each plasma, while the apparatus is further provided with substrate positioning means for bringing and/or keeping at least a part of a substrate in such a position in a process chamber that the substrate contacts the plasma, while the apparatus is provided with a second deposition source, which second deposition source is arranged to deposit at least one second deposition material on the substrate as the same time as the plasma cascade source, while the functional layer is no catalytically active layer.

With this apparatus, functional layers consisting of different material can be manufactured relatively fast and with a high uniformity over a large surface. Here, use of the plasma cascade source offers the above-mentioned advantages.

Further elaborations of the invention are described in the subclaims. The invention will now be explained on the basis of two exemplary embodiments and with reference to the drawing, in which:

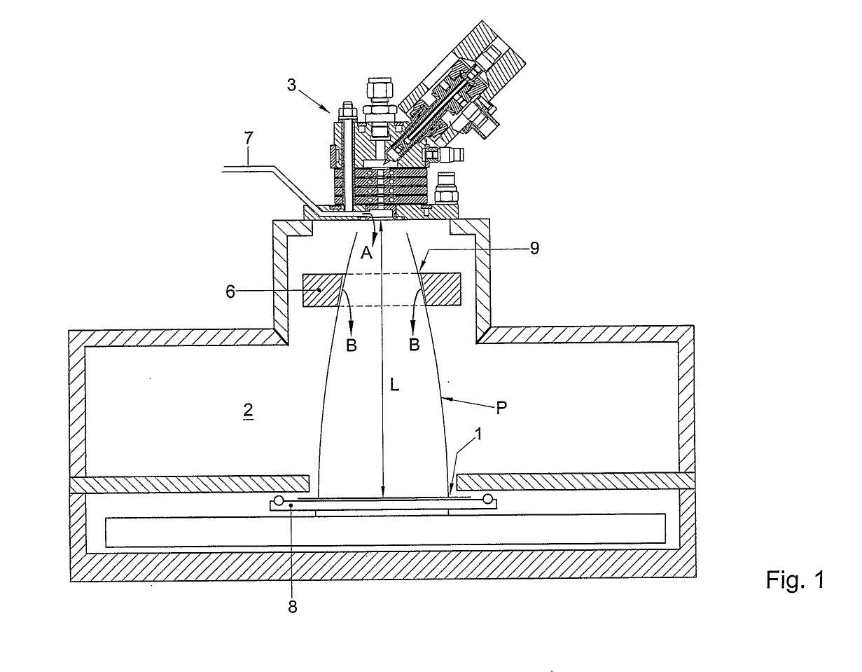

FIG. 1 shows a diagrammatic cross-sectional view of a first exemplary embodiment of an apparatus for manufacturing a functional layer consisting of two or more materials;

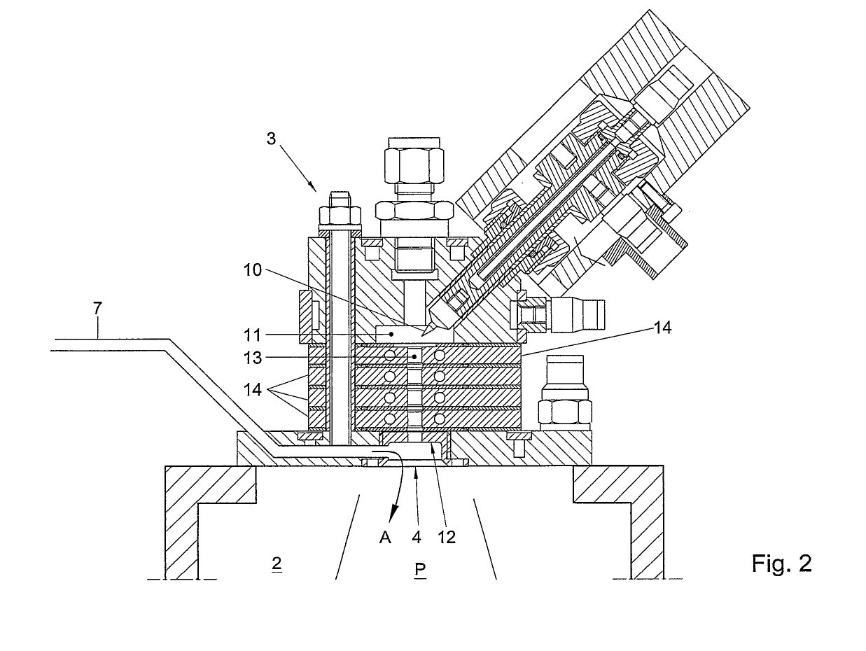

FIG. 2 shows a detail of the cross-sectional view shown in FIG. 1, in which the plasma cascade source is shown; and

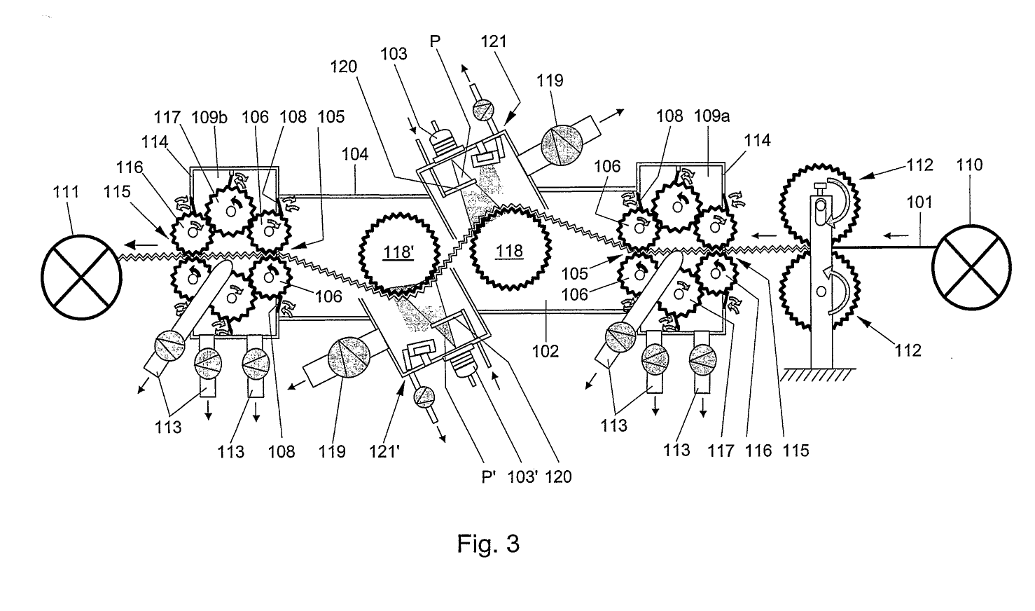

FIG. 3 shows a second exemplary embodiment of the invention.

FIGS. 1 and 2 show an apparatus for manufacturing a functional layer containing two or more materials. The apparatus shown in FIGS. 1 and 2 is provided with a PECVD process chamber 2 on which a DC (direct current) plasma cascade source 3 has been provided. The DC plasma cascade source 3 is arranged to generate a plasma P with DC voltage. The apparatus is provided with a substrate holder 8 to keep one substrate 1 opposite an outflow opening 4 of the plasma source 3 in the process chamber 2.

As is shown in FIG. 2, the plasma cascade source 3 is provided with a cathode 10 located in a source chamber 11 and an anode 12 located at a side of the source 3 facing the process chamber 2. Via a relatively narrow channel 13 and the plasma outflow opening 4, the source chamber 11 opens into the process chamber 2. The apparatus is dimensioned such that the distance L between the substrate 1 and the plasma outflow opening 4 is approximately 200 mm-300 mm. This allows the apparatus to have a relatively compact design. The channel 13 is bounded by cascade plates 14 mutually insulated from one another and the anode 12. During use, the process chamber 2 is maintained at a relatively low pressure, particularly lower than 50 mbar, and preferably lower than 5 mbar. Of course, inter alia the treatment pressure and the dimensions of the process chamber need to be such that deposition can still take place. In practice, the treatment pressure in a process chamber of the present exemplary embodiment is found to be at least approximately 0.1 mbar for this purpose. The pumping means needed for obtaining this treatment pressure are not shown in the drawing. Between the cathode 10 and anode 12 of the source 3, a plasma is generated, for instance by ignition of an inert gas present therebetween, such as argon. When the plasma has been generated in the source 3, the pressure in the source chamber 11 is higher than the pressure in the process chamber 2. The pressure in the source chamber may, for instance, be substantially atmospheric and be in the range of 0.5-1.5 bar. Because the pressure in the process chamber 2 is considerably lower than the pressure in the source chamber 11, a part of the generated plasma P expands such that it extends via the relatively narrow channel 7 from the outflow opening 4 into the process chamber 2 to contact the surface of the substrate 1.

The apparatus is provided with a gas supply channel 7 to supply a flow of a gas A to the plasma P in the anode plate 12 of the source 3. The gas A may, for instance, comprise a functional material to be deposited. Further, the apparatus comprises a sputtering electrode 6 arranged in the process chamber 2. In the Figure, the sputtering cathode 6 is arranged at a distance from the cascade source 3. However, this cathode 6 may also be located near the cascade source 3 or abut this source 3. The sputtering electrode 6 contains at least one material B to be sputtered onto the substrate, for instance a carrier material. The sputtering electrode 6 is arranged such that, during use, the plasma P generated by the plasma source 3 sputters the material B from the sputtering electrode 6 onto the substrate 1. For this purpose, the sputtering electrode 6 is designed as a cylindrical body having a concentric passage 9 through which the plasma P extends from the source 3 to the substrate 1 during use. For the purpose of sputtering, during use, the electrode 6 can be put under such an electric tension that plasma ions strike the electrode 6 and eject electrode material B. In addition, plasma ions can spontaneously strike the electrode 6 due to an inherently high kinetic energy of those ions of the expanding plasma P. In the present exemplary embodiment, the sputtering electrode 6 and the gas supply channel 7 are shown as being separate from each other. In addition, the gas supply channel 7 and the sputtering electrode can, for instance, be designed in an integrated manner to supply the materials A and B at substantially the same location to the plasma P.

During use of the exemplary embodiment shown in FIGS. 1 and 2, the materials A and B are deposited on the substrate 1 arranged in process chamber 2. The material A supplied by the channel 7 is carried along by the plasma P flowing from the source 3 and deposited on the substrate 1. The material B from the electrode 6 is simultaneously supplied to the substrate 1 by sputtering. This method makes it possible to apply a functional layer, containing the materials A and B, to the substrate 1 in a very uniform manner. Since the plasma cascade source operates under DC voltage to generate the plasma, the functional layer can simply, substantially without adjustment during deposition, be grown at a constant growth rate. This is advantageous over use of a HF plasma source, where continual adjustment is usually required. Furthermore, with the DC plasma cascade source 3, a relatively high deposition rate can be achieved. During the deposition of the materials A, B, to the substrate 1 a specific electric potential can further be applied, such as by DC, pulsed DC and/or RF biasing, for instance for further promoting homogeneity of the deposition. In addition, the substrate 1 can be heated to a specific treatment temperature using heating means (not shown) known from practice.

FIG. 3 shows a second exemplary embodiment of an apparatus for manufacturing a web to which a functional layer has been applied. The second exemplary embodiment is arranged to deposit a functional layer consisting of two or more materials in line on a substrate web in the form of a long, sheet-shaped substrate 101 which can be rolled up. This apparatus is provided with a substrate supply roller 110 on which the substrate sheet 101 has been wound. The supply roller 110 is arranged to supply the sheet 101 to a process chamber 102 during use. The apparatus further comprises a discharge roller to discharge the substrate 101 which can be rolled up from the process chamber 102. Between the supply roller 110 and the process chamber 102, a pair of cooperating rollers 112 are arranged to deform the substrate 101 unrolled from the supply roller 110. Cooperating outer circumferences of the rollers 112, engaging the substrate sheet 101, are provided with engaging teeth, such that the rollers 112 serrate the sheet 101 during use. Optionally, these rollers may be dispensed with in the apparatus when a flat substrate web is desired, such as for instance a film provided with a coating for manufacturing windows for, for instance, automobiles, which windows are provided with heat-resistant, anti-reflection or similar optical filters as a result of the coated films.

The second exemplary embodiment is provided with two pre-chambers 109 arranged on both sides of the process chamber 102. The process chamber 102 is separated from the pre-chambers 109 by a wall 104. The wall 104 of the process chamber 102 is provided with passages 105 for transport of the substrate sheet 101 between the process chamber 102 and the pre-chambers 109. In each passage 105, two inner feed-through serration rollers 106, the outer circumferences of which are provided with teeth engaging the serrations of the sheet 101. The wall 104 of the chamber 102 is further provided with swiveling closing flaps 108 extending to the inner feed-through serration rollers 106 to obtain a good connection between those serration rollers 106 and the chamber wall 104. Each pre- chamber 109 is provided with pumping means 113 to maintain that chamber 109 at a relatively low pressure. An outer wall 114 of each pre-chamber 109 is also provided with a passage 115 to transport the substrate sheet 101 into and out of that pre-chamber 109 from and to an environment, respectively. In each of the passages 115, two outer feed-through serration rollers 116 arranged opposite each other are arranged, of which the outer circumferences engage the serrations of the sheet 101. Each pre-chamber 109 is further provided with closing flaps 108 to obtain a good connection between these external feed-through serration rollers 116 and chamber outer wall 114. Finally, in each pre-chamber 109, intermediate serration rollers 117 are arranged, which mechanically couple the outer feed-through rollers 116 to the inner feed-through rollers 106. The transport passage provided by the feed-through rollers 106, 116 to introduce the sheet 101 from an environment into the process chamber 102 and vice versa relatively tightly connects to the sheet 101, so that little environmental air can reach the process chamber 102. In this manner, the pressure in the process chamber 102 can be maintained relatively low compared to an environmental pressure.

The process chamber 102 is provided with two plasma cascade sources 103, 103′ arranged to generate two plasmas P, P′. Moreover, the cascade sources are arranged such that, during use, these sources 103,103′ are directed to substrate surfaces facing away from each other of the substrate 101 supplied into the process chamber 102 to be able to bring both substrate surfaces into contact with plasma P, P′. Near each plasma source 103, 103′, a gas shower head 120 is arranged in the process chamber 102 to supply a material to be deposited to the respective plasmas P, P′. Furthermore, near each plasma cascade source 103, 103, a separate sputtering source 121, 121′ is arranged to deposit material on the substrate 101 through a sputtering process. The process chamber 102 further comprises pumping means 119 to maintain that chamber at a desired, low pressure.

In the process chamber 102, opposite each plasma source 103, 103′, a heatable substrate positioning roller 118, 118′ is arranged to lead the substrate 101 supplied into the process chamber 102 along the respective plasma source P, P′ and to bring to and/or maintain it at a desired treatment temperature. The arrangement of the positioning rollers 118, 118′ and the plasma sources 103, 103′ allows material to be deposited on both sides of the substrate sheet 101 in the process chamber 102.

During use of the second exemplary embodiment, the substrate sheet 101 is supplied by the supply roller 110 to the roller pair 112. The sheet 101 is then provided with serrations by this roller pair 112. Next, the sheet 101 is introduced into the process chamber 102 through the pre- chamber 109a shown on the right in the FIG. 3. In the process chamber 102, the one material and the other material are deposited on the one side of the serrated sheet 101 near the one positioning roller 118.

Deposition of the one material preferably takes place under the influence of the plasma P of the one plasma cascade source 103. The sputtering source 121 can simultaneously deposit the other material on the substrate sheet 101. Deposition of material by the plasma source 103 and the sputtering source 121 can simply be adapted to each other in order to obtain desired chemical and morphological properties of the functional layer.

After deposition of material on the one side, the other side of the substrate sheet 101 is processed in a similar manner by the other plasma source 103′ and sputtering source 121′ in order to deposit a functional layer on that side. During the treatment of the sheet 101, the positioning rollers 118, 118′ can be brought to a desired treatment temperature by heating means (not shown), so that the sheet 101 obtains a desired deposition temperature. After the treatment, the sheet 101 is discharged from the process chamber 102 through the left pre-chamber 109b and rolled up on the discharge roll 111.

The second exemplary embodiment can be used to manufacture a functional layer according to an in-line process, which is very attractive from a commercial point of view. In addition, the composition of the functional layer can be controlled well. Advantages of use of the cascade sources 103, 103′ have already been discussed in the above. The serrated sheet 101 provided with the functional layer can simply be processed further. Instead of the pair of rollers 112 for providing the corrugation or serrations, flat wheel rollers may also be used. Instead of a sheet 101, a film may also be used from, for instance, PET.

It goes without saying that the invention is not limited to the exemplary embodiments described. Various modifications are possible within the scope of the invention as set forth in the following claims.

For instance, the substrate may comprise carrier material, such as an oxidized metal and/or oxidized semi-conductor, for instance aluminum oxide, silicon dioxide, titanium dioxide and/or zirconium dioxide. In addition, the substrate may comprise a material which is oxidizable to a carrier material. In the latter case, the deposition may be carried out in an environment containing oxygen for the oxidation of that substrate material.

In addition, the sputtering electrode may, for instance, be provided with fluid supply channels to introduce said volatile compounds of catalytically active components to be applied into the plasma.

The sputtering cathode may further be designed in various manners, and comprise, for instance, a planar, tubular, U-shaped or hollow cathode or be designed in a combination of these or other cathode forms.

The carrier material to be deposited may further be the same as the material of the substrate or differ therefrom.

Further, a volatile compound may be introduced into the process chamber in order to be deposited on the substrate. Moreover, such a volatile compound may contain at least one precursor material which decomposes in the material to be deposited before the material has reached the substrate. Decomposition of that material may occur, for instance, spontaneously and/or under the influence of a plasma.

Furthermore, the deposition material may be deposited such that the chemical composition of the material deposited measured over distances of 5 cm, preferably over a distance of 10 cm, more particularly over a distance of 20 cm, differs less than 10%, particularly less than 5% and more particularly less than 1%. In this manner, a functional layer with a very homogenous composition can be obtained.

Further, different types of substrates of different forms may be used, for instance hard and/or porous substrates of various materials.

Furthermore, various methods may be used to clean a sputtering cathode before and after use, for instance by now and then reversing the polarity of the cathode using a suitable electric tension.

Although for sputtering, generally lower pressures are desired than for depositing materials with the aid of a cascade arc, the two processes may still be combined by using the cascade arc at a much lower pressure than conventional. For this purpose, the expansion channel in the cascade source may be provided with a smaller diameter. When starting the source, a higher starting pressure may be used after which the pressure may then be adjusted downwards. Also, in the deposition chamber, so-called skimmers may be used, where, with the aid of pumps, a differential pressure on both sides of the skimmers can be maintained. A skimmer is a type of diaphragm or a narrowing in the process chamber. The sputtering process may, for instance, be located on the low-pressure side of the skimmer while the cascade source is arranged on the high-pressure side of the skimmer.

It is clear that the invention is not limited to the exemplary embodiments described but that various modifications are possible within the framework of the invention as defined by the claims. For instance, instead of a plasma cascade source, a different type of plasma source may be used as well.

1. A method for manufacturing a functional layer, comprising:
introducing a substrate into a process chamber,
generating a plasma by a DC plasma cascade source;
depositing a first deposition material on the substrate under the influence of the plasma, wherein, at the same time, applying a second deposition material to the substrate with a second deposition process, wherein the functional layer has no catalytic function.

2. A method according to claim 1, wherein the first deposition material is supplied to the plasma outside the at least plasma source in the process chamber.

3. A method according to claim 1, wherein a volatile compound of the first deposition material is supplied to the plasma for the deposition.

4. A method according to claim 3, wherein the volatile compound contains a precursor material which decomposes the first deposition material in the process chamber before the first deposition material has reached the substrate.

5. A method according to claim 1, wherein the second deposition process is PECVD, CVD, PVD, sputtering, hollow-cathode sputtering, vapor deposition using boats, e-beam, and/or supported by an ion process, ion plating, microwave deposition, ICP (inductive coupled plasma), parallel-plate PECVD, and/or honey comb electrode structures.

6. A method according to claim 1, wherein a sputtering electrode comprising the first and/or the second deposition material is arranged in the process chamber, wherein the plasma is brought into contact with said sputtering electrode to sputter the substrate with the first and/or the second deposition material of the electrode.

7. A method according to claim 6, wherein the plasma is passed at least partly through a passage of the sputtering electrode to contact the plasma with the electrode.

8. A method according to claim 7, wherein the sputtering electrode contains compressed powders of the first and/or second deposition materials to be deposited on the substrate.

9. A method according to claim 1, wherein the substrate comprises sheet material.

10. A method according to claim 1, wherein the substrate is moved in the process chamber at least in such a manner that each time a different part of the substrate contacts the plasma.

11. A method according to claim 1, wherein the substrate is brought from an environment into the process chamber and is discharged from the process chamber to the environment while the deposition material is deposited on the substrate in the process chamber.

12. A method according to claim 1, wherein the substrate is substantially non-porous and comprises a metal or plastic.

13. A method according to claim 1, wherein the substrate comprises a carrier material.

14. A method according to claim 1, wherein the substrate comprises a metal and/or an alloy.

15. A method according to claim 1, wherein the substrate comprises corrugated material.

16. A method according to claim 1, wherein the substrate is substantially porous.

17. A method according to claim 1, wherein the first and/or second deposition material is deposited such that the chemical composition of the deposited material measured over distances of 5 cm differs by less than 10%.

18. A method according to claim 1, wherein the substrate is adjusted to a particular electrical potential by DC, pulsed DC and/or RF biasing.

19. A method according to claim 1, wherein the substrate is adjusted to a treatment temperature.

20. An apparatus for manufacturing a functional layer on a substrate, comprising:
a process chamber:
a DC plasma cascade source configured to generate a plasma;
a first deposition material source configured to introduce a first deposition material into the plasma;
a substrate positioning device configured to bring and/or keep at least a part of a substrate in such a position in the process chamber that the substrate contacts said plasma;
a second deposition material source, configured to deposit a second deposition material on the substrate at the same time as the plasma source, wherein the functional layer is no catalytically active layer.

21. An apparatus according to claim 20, wherein the second deposition material source is a VD source, including a CVD source, a PVD source, or a PECVD source.

22. An apparatus according to claim 20, wherein the second deposition material source is configured to carry out deposition processes including: PECVD, CVD, PVD, sputtering, hollow-cathode sputtering, vapor deposition using boats, e-beam, and/or supported by an ion process, ion plating, microwave deposition, ICP (inductive coupled plasma), parallel-plate PECVD, and/or honeycomb electrode structures.

23. An apparatus according to claim 21, wherein the second deposition material source comprises a sputtering electrode containing the first and/or the second deposition material to be deposited, wherein the sputtering electrode is positioned such that, during use, the plasma generated by the plasma source sputters the first and/or the second deposition material from the sputtering electrode onto the substrate.

24. An apparatus according to claim 23, wherein the sputtering electrode is arranged downstream of the plasma source and is provided with a plasma passage to allow the plasma to pass from the source to the substrate.

25. An apparatus according to claim 23, wherein the sputtering electrode abuts the plasma source.

26. An apparatus according to claim 20, further comprising a fluid supply channel configured to supply a the first deposition material to be deposited, being in a volatile state, to the plasma.

27. An apparatus according to claim 26, wherein the sputtering electrode is provided with the fluid supply channel.

28. An apparatus according to claim 20, further comprising two DC plasma cascade sources configured to generate two plasmas, wherein the two DC plasma cascade sources and the substrate positioning means device are positioned such that, during use, opposite sides of the substrate contact the plasmas generated by the two DC plasma cascade sources to deposit material on the opposite sides of the substrate.

29. An apparatus according to claim 20, further comprising a substrate supply roller and discharge roller, respectively, configured to supply and discharge, respectively, a substrate that can be rolled up to and from the process chamber respectively.

30. An apparatus according to claim 20, wherein a wall of the process chamber is provided with a passage to pass the substrate into and/or out of the process chamber.

31. An apparatus according to claim 30, wherein at least a part of the passage of the process chamber wall is bounded by oppositely arranged feed-through rollers configured to engage a part of the substrate disposed between them during use, for feed-through of the substrate.

32. An apparatus according to claim 29, further comprising a deformation means member configured to deform the substrate which has unrolled from the supply roller.

33. An apparatus according to claim 32, wherein the deformation means member is configured to corrugate and/or serrate the substrate.

34. An apparatus according to claim 20, wherein the first and/or second deposition material is vapor deposited on the substrate.

35. An apparatus according to claim 20, further comprising a separate sputtering source configured to sputter material onto the substrate.
